(19) United States
(12) Patent Application Publication
(10) Pub. No.: US 2006/0104012 A1
(43) Pub. Date: May 18, 2006

(54) Electronic book device

(75) Inventors: Chung-Cheng Hsieh, Banciao City (TW); Chih-Kang Chang, Taipei City (TW); Jehng-Shyurng Chen, Jhonghe City (TW)

Correspondence Address: Dougherty & Troxell;ONE SKYLINE PLACE, SUITE 1404, 5205 LEESBURG PIKE, FALLS CHURCH, VA, 22041, US

(73) Assignee: Brotherbear Corporation

(21) Appl. No.: 10/988,760

(22) Filed: Nov. 16, 2004

(51) Int. Cl. H05K 5/00; H05K 7/00

(52) U.S. Cl. 361/679

(57) ABSTRACT

An electronic book device including a housing, for positioning an electronic book therein, at least one transmitting module, positioned inside the housing, for selecting an icon on the electronic book and accordingly transmitting a wireless signal, an antenna module, positioned inside the housing, for receiving the wireless signal transmitted from the transmitting module, a pointing module, positioned inside the housing and coupled to the antenna module, for receiving the wireless signal and converting it into at least one coordinate value, and a control module, coupled to the pointing apparatus, for receiving the coordinate value and converting it into sound signal and then outputting.

### BACKGROUND OF THE INVENTION

1. Field of the Invention

The present invention relates to an electronic book and, more particularly, relates to an electronic book device, which can select an icon or character(s) on the electronic book by the transmitting module and output the corresponding audio signal to a speaker.

2. Description of the Related Art

Please refer to the FIG. 4, which illustrates an electronic book device manufactured by U.S Leapfrog cooperation. As shown in the FIG. 4, the conventional electronic book device comprises a body 110 and a pointing module 120, and has a transmitting module 111 and an antenna 112 positioned inside the body 110, thereby, the pointing module 120 can receive the magnetic flux varying of the antenna 120 when the pointing module 120 is pointed a certain position on the electronic book 100, and converts the magnetic flux varying into voltage signal and transmits it to the body 110 by way of wire, the body 110 executes an analog to digital converting and mapping to relative sound file and outputting to a speaker. However, the conventional electronic book device has the following drawbacks: 1. its operation is cumbersome due to the body 110 being connected to the pointing module 120 by way of wire; 2. The antenna 112 may be oxidized due to long term exposure in the air or coordinate-shifted errors due to humidity in the air or due to vibration. Furthermore, the signaling may malfunction due to the electronic book's acquired wetness, such that the signal may be fully shielded by the wetness in the electronic book under serious wetness condition. Finally, conventional books use a wired pen to navigate the electronic book, thus allowing only one user to use the pointing module, while depriving other users from simultaneously participating in the multi-user interactive learning function.

According to the aforesaid description, there needs an electronic book device that can select an icon on the electronic book, without relying on the wired transmitting module and output the corresponding sound signal to a speaker.

### SUMMARY OF THE INVENTION

The present invention has been accomplished under the circumstances in view. It is therefore the main object of the present invention to provide an electronic book device, which eliminates the aforesaid drawbacks.

According to one aspect of the present invention, the object of the present invention is to provide an electronic book device, which can select an icon or character(s) on the electronic book by the transmitting module and output the corresponding sound signal to a speaker.

According to one aspect of the present invention, another object of the present invention is to provide a multi-user electronic book device, which can be used by multiple users, such that the users can simultaneously select an icon or character(s) on the electronic book by the transmitting module and output the corresponding sound signal to a speaker according to the receiving sequence.

To overcome the drawbacks of the aforesaid prior art, the electronic book device of the present invention comprises: a housing, for positioning an electronic book therein; at least one transmitting module, positioned inside the housing, for selecting an icon on the electronic book and accordingly transmitting a wireless signal; an antenna module, positioned inside the housing, for receiving the wireless signal transmitted from the transmitting module; a pointing module, positioned inside the housing and coupled to the antenna module, for receiving the wireless signal and converting it into at least one coordinate value; and a control module, coupled to the pointing module, for receiving the coordinate value and converting it into sound signal for outputting.

These and other features, aspects, and advantages of the present invention will become apparent by a review of the following detailed description of the preferred embodiment of the invention and by reference to the following drawings.

### BRIEF DESCRIPTION OF THE DRAWINGS

FIG. 1 illustrates an assembly view of an exemplary electronic book device according to one preferred embodiment of the present invention.

FIG. 2 illustrates a block diagram of an exemplary electronic book device according to one preferred embodiment of the present invention.

FIG. 3 illustrates a simplified block diagram of the control module 50 according to one preferred embodiment of the present invention.

FIG. 4 illustrates a conventional electronic book device manufactured by U.S Leapfrog cooperation.

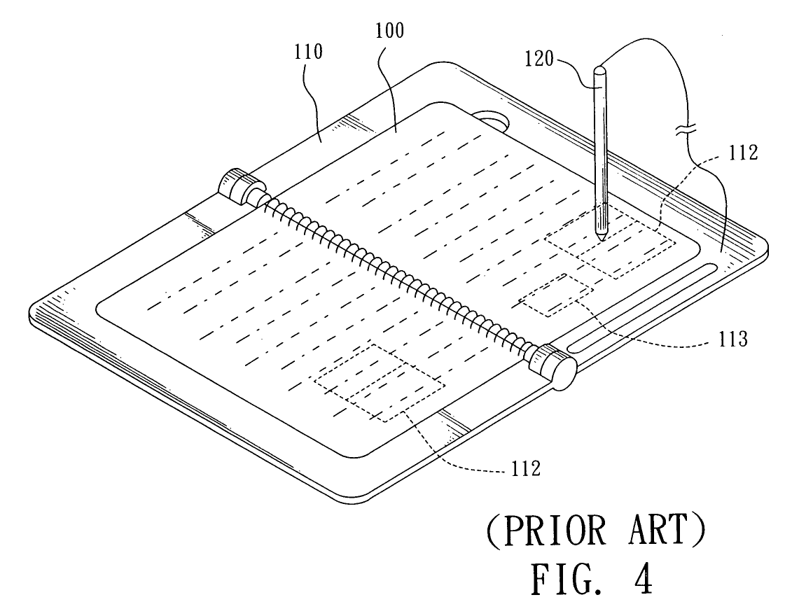

### DETAILED DESCRIPTION OF THE PREFERRED EMBODIMENT

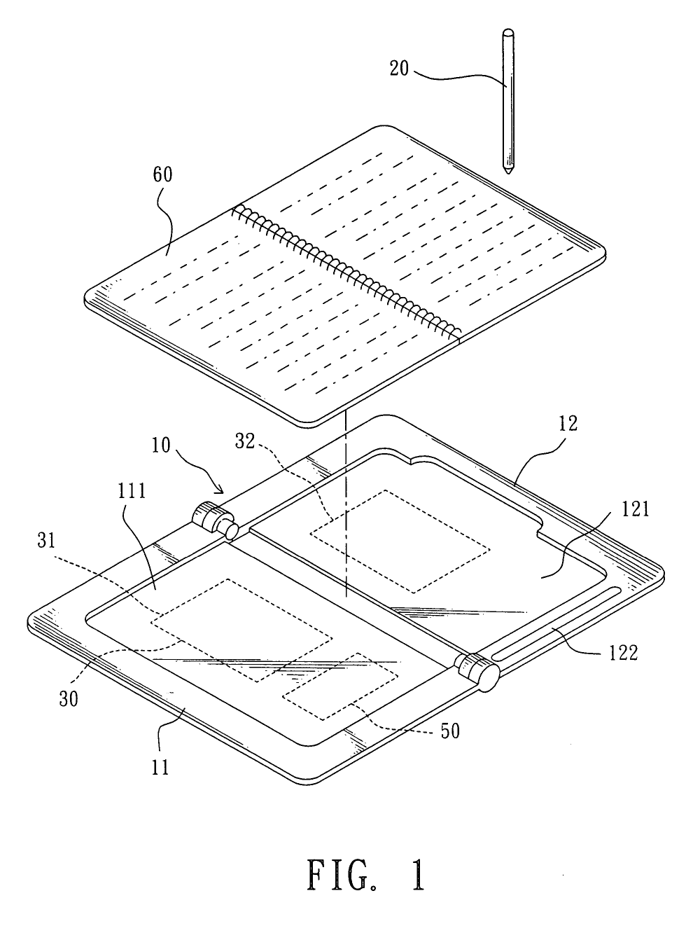

Referring to FIG. 1, which illustrates an assembly view of the electronic book device according to one preferred embodiment of the present invention. As shown in the FIGS. 1-3, the electronic book device of the present invention comprises: a housing 10; at least one transmitting module 20; an antenna module 30; a pointing module 40 and a control module 50.

The housing 10 is made by insulation materials, for example but not limited to plastic material, it further comprises a left housing 11 and a right housing 12, which can be connected and folded to close upon each other. In additionally, for the purpose of illustration, the left housing 11 and right housing 12 for example but not limited respectively comprises a concave space 111, 121 on its inner surface for positioning the electronic book 60. The electronic book 60, which has been well-known in the art, further comprises at least one icon, figure, characters or other contents (collectively hereinafter “graphical object”). The electronic book 60 is formed, for example but not limited to a foldaway, single sheet, jigsaw puzzle or solid object type, and the electronic book 60 can be made by wood, cloth, leather, plastic and so on, and can have graphical objects such as printed icon(s), character(s) or figure(s) thereon. The electronic book device 60 of the present invention will output corresponding audio signals when the transmitting module 20 selects figure, characters or other contents on the electronic book 60, as directed by the user or users.

In addition, the right housing 12, for example but not limited to further comprise a groove 122 for securing the transmitting module 20 when not in use, and the groove 122 is preferably located deeper than the concave space 121. In fact, the right housing 12 also can be a plain-shaped housing without the concave space 122 on its inner surface. Furthermore, the shape of the housing 10 is not limited as aforesaid that comprises a left housing 11 and a right housing 12, it also can be a plain-shaped housing and can contain relative modules therein. It is noted that for a graphical object on the electronic book to be “selected” by the transmitting module 20, the user needs to place the transmitting module 20 to the proximity, e.g. directly above or touching, the object and activates the transmitting module 20.

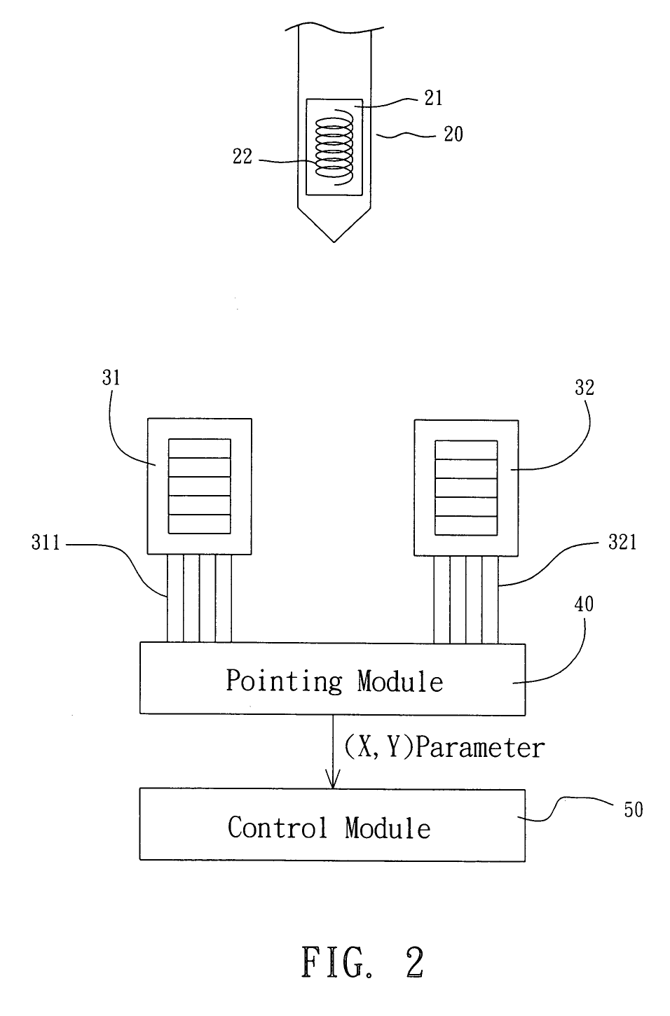

As shown in FIG. 2, which illustrates a simplified block diagram of the electronic book device according to one preferred embodiment of the present invention. As shown in the Figs., the transmitting module 20 of the present invention, positioned inside the housing 10, disposed to select an icon or character(s) on the electronic book 60 and accordingly transmitting a wireless signal, wherein the wireless signal may be a radio frequency or an Infra Red (IR) signal, further comprises a printed circuit board 21 and an oscillating coil 22 therein. The oscillating coil 22 is positioned on the printed circuit board 21 for radiating a varying magnetic flux of a magnetic field, so that the antenna module 30 can determine the pointed coordinate value by the transmitting module 20 according to the varying magnetic flux. The shape of the transmitting module 20 is not limited to the pen-shaped module, and other shapes that can contain the printed circuit board 21 and oscillating coil 22 also can be used.

The antenna module 30 further comprises: a first antenna 31, positioned in a first location in the housing 10, for example but not limited to the left housing 11, for receiving the wireless signal transmitted from the transmitting module 20 and accordingly transmitting a plurality of first magnetic field strength signals 311; and a second antenna 32, positioned in a second location in the housing 10, for example but not limited to the right housing 12, for receiving the wireless signal transmitted from the transmitting module 20 and accordingly transmitting a plurality of second magnetic field strength signals 321. The first antenna 31 and the second antenna 32 are formed by printed antenna, or made by a winding or coil of insulated copper wire and the first 31 and second antenna 32 are located at different positions on the housing 10.

The pointing module 40, also referred as locating module, is positioned inside the housing 10 and coupled to the antenna module 30, for receiving the first magnetic field strength signals 311 and second magnetic field strength signals 321 and executing an analog to digital converting process to convert them into at least one coordinate value that includes x and y coordinate values, and outputting the coordinate values to the control module 50 by an interface, for example but not limited to RS-232 interface.

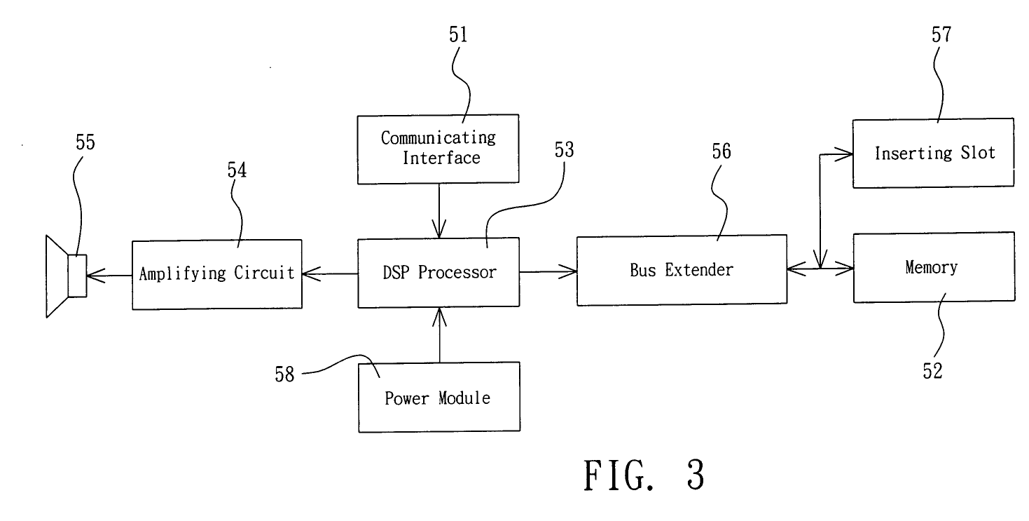

FIG. 3 illustrates an exemplary block diagram of the control module 50 according to one preferred embodiment of the present invention. As shown in the FIG., the control module 50 of the present invention is positioned inside the housing 10 and coupled to the pointing apparatus 40. It further comprises: a communicating interface 51; a memory 52; a DSP processor 53; an amplifying circuit 54; and a sound outputting device 55.

The communicating interface 51, which may be for example but not limited to a RS-232 interface, is coupled to the pointing module 40 for receiving the coordinate value; the memory 52, which may be, for example but not limited to, a flash memory or read only memory and which may have a size of, for example but not limited to, 4 MB, is used for storing at least one sound data file which contents are corresponding to the contents of the electric book 60.

The DSP processor 53 is coupled to the pointing module 40 and the memory 52, for executing a mapping process to map a coordinate value to an address of the memory 52. When it receives the coordinate value, the DSP processor 53 reads and decodes the voice data file from the memory 52 and outputs a sound (or audio) signal through the sound (or audio) outputting device 55. The amplifying circuit 54, which may be, for example but not limited to, a transistor amplifying circuit, is coupled to the DSP processor 53 for amplifying the sound (or audio) signal. The sound outputting device 55, which may be for example but not limited to a speaker, is coupled to the amplifying circuit 54 for outputting the sound (or audio) signal.

In addition, the electronic book device of the present invention further comprises a bus extender 56 positioned between the DSP processor 53 and the memory 52 for extending the size of the memory 52 due to the addressing space of the DSP processor 53 being just 2 MB. Therefore, it needs a bus extender 56 if the size of the memory 52 is over 2 MB, so as to extend the addressing space of the DSP processor 53 to 4 MB. In addition, the electronic book device of the present invention further comprises an inserting slot 57 and a power module 58, wherein, the inserting slot 57 is coupled to the bus extender 56 for connecting to an external memory card device (not shown), while the power module 58 is coupled to the all elements of the book device for supplying power to the electronic book device. The user must change the memory card corresponding to the electronic book 60 and insert it into the inserting slot 57 when the user changes the electronic book 60.

Furthermore, the present invention also provide a method of operating an electronic book, which comprises the steps of: providing an electronic book 60, the electronic book 60 having a plurality of graphical objects in predetermined coordinates on each page of the book (step 1); positioning the electronic book 60 in a housing 10, the housing 10 comprising a transmitting module 20, an antenna module 30, a pointing module 40 and a control module 50 (step 2); selecting a graphical object on the book 60 and transmitting a wireless signal upon selecting the graphical object, using the transmitting module 20 (step 3); receiving the wireless signal transmitted by using the antenna module 30 (step 4); receiving the wireless signal and converting it into at least one coordinate value by using the pointing module 40 (step 5); and receiving said coordinate value and converting it into an audio signal for outputting using the control module 50 (step 6).

Wherein the step of receiving the wireless signal transmitted comprises: receiving the wireless signal using a first antenna 31, which is positioned in a first location in the housing 10 (step 41); generating a plurality of first magnetic field strength signals by the first antenna 31 (step 42); receiving the wireless signal using a second antenna 32, which is positioned in a second location in the housing 10 (step 43); generating a plurality of second magnetic field strength signals by the second antenna 32 (step 43).

Although particular embodiments of the invention have been described in detail for purposes of illustration, various modifications and enhancements may be made without departing from the spirit and scope of the invention. Accordingly, the invention is not to be limited except as by the appended claims.

1-20. (canceled)

21. An electronic book device comprising:
a) an electronic book;
b) a housing having an interior, the electronic book being inserted into the interior;
c) at least one transmitting module selecting a graphic object of the electronic book and transmitting a wireless signal, and having a printed circuit board and an oscillating coil connected to the printed circuit board, the oscillating coil radiating a magnetic flux of a magnetic field;
d) an antenna module located in the housing and receiving the wireless signal from the at least one transmitting module and generating at least one strength signal;
e) a pointing module located in the housing and connected to the antenna module, the pointing module receiving and converting the strength signal into at least one coordinate value; and
f) a control module connected to the pointing module, the control module receiving and converting the at least one coordinate value into a sound signal, the control module outputting the sound signal.

22. The electronic book device according to claim 21, wherein the electronic book is selected from a group of electronic books consisting of a foldaway, a single sheet, a jigsaw puzzle, and a solid object, the electronic book is made of a material selected from a group consisting of wood, cloth, leather, and plastic, the electronic book has printed characters and figures located thereon.

23. The electronic book device according to claim 21, wherein the housing includes a left housing connected to a right housing, the electronic book is selectively located between the left housing and the right housing.

24. The electronic book device according to claim 21, wherein the housing includes a left housing, a right housing, and a hollow interior located between the left housing and the right housing, the electronic book is selectively inserted into the hollow interior.

25. The electronic book device according to claim 21, wherein the wireless signal is a signal selected from a group consisting of a radio frequency signal and an infra red signal.

26. The electronic book device according to claim 21, wherein the antenna module includes:
a) a first antenna receiving the wireless signal from the at least one transmitting module and transmitting a plurality of first magnetic field strength signals; and
b) a second antenna receiving the wireless signal from the at least one transmitting module and transmitting a plurality of second magnetic field strength signals.

27. The electronic book device according to claim 26, wherein the first antenna and the second antenna are selected from a group consisting of at least one printed antenna and a winding of insulated copper wire.

28. The electronic book device according to claim 26, wherein the pointing module determines a position of the graphic object selected by the at least one transmitting module by executing an analog to digital process to convert the plurality of first magnetic field strength signals and the plurality of second magnetic field strength signals into the at least one coordinate value.

29. The electronic book device according to claim 21, wherein the control module includes:
a) a DSP processor;
b) a memory storing at least one audio data file;
c) a communicating interface connected between the pointing module and the DSP processor, the DSP processor receiving the at least one coordinate value through the communicating interface and mapping to the at least one audio data file n the memory, the DSP processor reading and decoding the at least one audio data file, an outputting an audio signal;
d) an amplifying circuit connected to the DSP processor and amplifying the audio signal; and
e) an audio outputting device connected to the amplifying circuit and outputting the audio signal.

30. The electronic book device according to claim 29, wherein the memory is selected from a group consisting of a flash memory and a read only memory, and the communicating interface is an RS-232 interface.

31. The electronic book device according to claim 29, further comprising a bus extender located between the DSP processor and the memory extending a size of the memory.

32. The electronic book device according to claim 31, further comprising an inserting slot connected to the bus extender, the inserting slot selectively receiving an external memory card device.

33. The electronic book device according to claim 29, further comprising a power module supplying power to the electronic book.

34. The electronic book device according to claim 26, wherein the first antenna and the second antenna are spaced apart on the housing.

35. A method for operating an electronic book device, which comprises the steps of:
a) selecting an electronic book having a plurality of graphic objects located at predetermined coordinates on each page of the electronic book;
b) positioning the electronic book in a housing having an interior, the housing having a transmitting module, an antenna module, a pointing module, and a control module;
c) selecting one of the plurality of graphic objects and transmitting a wireless signal utilizing the transmitting module, the transmitting module including a printed circuit board and an oscillating coil connected to the printed circuit board, the oscillating coil radiating a magnetic flux of a magnetic field;
d) receiving the wireless signal from the at least one transmitting module and generating at least one strength signal utilizing that antenna module;
e) receiving and converting the strength signal into at least one coordinate value utilizing the pointing module; and
f) receiving and converting the at least one coordinate value into a sound signal utilizing the control module, the control module outputting the sound signal.
